(19) United States
(12) Patent Application Publication
(10) Pub. No.: US 2018/0182939 A1
(43) Pub. Date: Jun. 28, 2018

(54) PACKAGE FOR AN ULTRAVIOLET EMITTING DEVICE

(71) Applicant: RayVio Corporation, Hayward, CA (US)

(72) Inventors: Saijin Liu, Hayward, CA (US); Douglas A. Collins, Hayward, CA (US); Yitao Liao, Redwood City, CA (US)

(21) Appl. No.: 15/389,308

(22) Filed: Dec. 22, 2016

(51) Int. Cl. H01L 33/58

(52) U.S. Cl. CPC H01L 33/58; H01L 2933/0058

(57) ABSTRACT

Embodiments of the invention include a light emitting diode (UVLED), the UVLED including a semiconductor structure with an active layer disposed between an n-type region and a p-type region. The active layer emits UV radiation. The UVLED is attached to a mount. A lens is disposed over the UVLED. A surface of the lens closest to the UVLED is the same width as the mount.

### BACKGROUND

### Description of Related Art

The bandgap of III-nitride materials, including (Al, Ga, In)—N and their alloys, extends from the very narrow gap of InN (0.7 eV) to the very wide gap of AlN (6.2 eV), making III-nitride materials highly suitable for optoelectronic applications such as light emitting diodes (LEDs), laser diodes, optical modulators, and detectors over a wide spectral range extending from the near infrared to the deep ultraviolet. Visible light LEDs and lasers can be obtained using InGaN in the active layers, while ultraviolet LEDs (UVLEDs) and lasers require the larger bandgap of AlGaN.

UVLEDs with emission wavelengths in the range of 230-350 nm are expected to find a wide range of applications, most of which are based on the interaction between UV radiation and biological material. Typical applications include surface sterilization, air disinfection, water disinfection, medical devices and biochemistry, light sources for ultra-high density optical recording, white lighting, fluorescence analysis, sensing, and zero-emission automobiles.

### BRIEF DESCRIPTION OF THE DRAWINGS

FIG. 1 illustrates a packaged UVLED.

FIG. 2 is a plan view of multiple pixels in a flip chip UVLED.

FIG. 3 is a cross sectional view of one pixel in the UVLED.

FIG. 4 illustrates a panel of lenses formed separately from a group of UVLEDs.

FIG. 5 illustrates a group of UVLEDs attached to a panel of mounts.

FIG. 6 illustrates a panel of lenses aligned with a panel of mounts and disposed in a vacuum chamber.

FIG. 7 illustrates dicing a panel of lenses bonded to UVLEDs disposed on a panel of mounts.

### DETAILED DESCRIPTION

Embodiments of the invention are directed to packages for UVLEDs, and methods of packaging UVLEDs.

Though the devices described herein are III-nitride devices, devices formed from other materials such as other III-V materials, II-VI materials, Si are within the scope of embodiments of the invention. The devices described herein may be configured to emit visible, UV A (peak wavelength between 340 and 400 nm), UV B (peak wavelength between 290 and 340 nm), or UV C (peak wavelength between 210 and 290 nm) radiation. The radiative power emitted by the UVLEDs described herein may be described as “light” for economy of language.

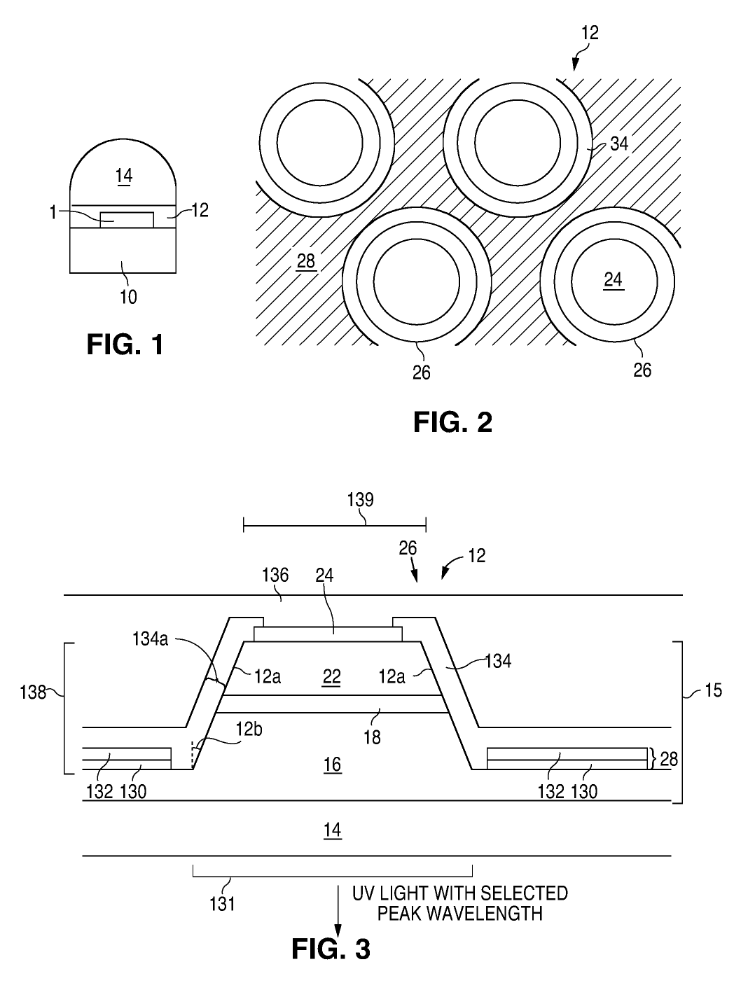

FIG. 1 illustrates a packaged LED according to embodiments of the invention. A UVLED 1, one example of which is described below in the text accompanying FIGS. 2 and 3, is attached to a mount. A lens 14 is disposed over the UVLED 1. A layer of transparent material 12 may be disposed between the lens 14 and the UVLED 1 and mount 10.

Commercially available UVA, UVB, and UVC LEDs may be used in the various embodiments. FIGS. 2 and 3 illustrate a portion of one example of the assignee's own UVB and UVC LEDs, which may be used in embodiments of the invention. FIG. 2 is a top down view of a portion of a UVLED composed of an array of UVLED pixels 12. FIG. 3 is a bisected cross-section of a single UVLED pixel 12. Any suitable UVLED may be used and embodiments of the invention are not limited to the structures illustrated in FIGS. 2 and 3.

The UVLEDs are typically III-nitride, and commonly GaN, AlGaN, and InGaN. The array of UV emitting pixels 12 is formed on a single substrate 14, such as a transparent sapphire substrate. Other substrates are possible. Although the example shows the pixels 12 being round, they may have any shape, such as square. The light escapes through the transparent substrate, as shown in FIG. 3. The pixels 12 may each be flip-chips, where the anode and cathode electrodes face a mount or other structure to which the UVLED is attached.

Semiconductor layers are epitaxially grown over the substrate 14. (The device may include one or more semiconductor layers, such as conductive oxides such as indium tin oxide, that are not epitaxially grown, but are deposited or otherwise formed.) An AlN or other suitable buffer layer (not shown) is grown, followed by an n-type region 16. The n-type region 16 may include multiple layers of different compositions, dopant concentrations, and thicknesses. The n-type region 16 may include at least one AlaGa₁₋ₐN film doped n-type with Si, Ge and/or other suitable n-type dopants. The n-type region 16 may have a thickness from about 100 nm to about 10 microns and is grown directly on the buffer layer(s). The doping level of Si in the n-type region 16 may range from 1×10¹⁶ cm⁻³ to 1×10²¹ cm⁻³. Depending on the intended emission wavelength, the AlN mole fraction “a” in the formula may vary from 0% for devices emitting at 360 nm to 100% for devices designed to emit at 200 nm.

An active region 18 is grown over the n-type region 16. The active region 18 may include either a single quantum well or multiple quantum wells (MQWs) separated by barrier layers. The quantum well and barrier layers contain AlₓGa₁₋ₓN/Al_{y}Ga_{1-y}N, wherein 0<x<y<1, x represents the AlN mole fraction of a quantum well layer, and y represents the AlN mole fraction of a barrier layer. The peak wavelength emitted by a UV LED is generally dependent upon the relative content of Al in the AlGaN quantum well active layer.

A p-type region 22 is grown over the active region 18. Like the n-type region 16, the p-type region 22 may include multiple layers of different compositions, dopant concentrations, and thicknesses. The p-type region 22 includes one or more p-type doped (e.g. Mg-doped) AlGaN layers. The AlN mole fraction can range from 0 to 100%, and the thickness of this layer or multilayer can range from about 2 nm to about 100 nm (single layer) or to about 500 nm (multilayer). A multilayer used in this region can improve lateral conductivity. The Mg doping level may vary from 1×10¹⁶ cm⁻³ to 1×10²¹ cm⁻³. A Mg-doped GaN contact layer may be grown last in the p-type region 22.

All or some of the semiconductor layers described above may be grown under excess Ga conditions, as described in more detail in US 2014/0103289, which is incorporated herein by reference.

The semiconductor structure 15 is etched to form trenches between the pixels 12 that reveal a surface of the n-type region 16. The sidewalls 12a of the pixels 12 may be vertical or sloped with an acute angle 12b relative to a normal to a major surface of the growth substrate. The height 138 of each pixel 12 may be between 0.1-5 microns. The widths 131 and 139 at the bottom and top of each pixel 12 may be at least 5 microns. Other dimensions may also be used.

Before or after etching the semiconductor structure 15 to form the trenches, a metal p-contact 24 is deposited and patterned on the top of each pixel 12. The p-contact 24 may include one or more metal layers that form an ohmic contact, and one or more metal layers that form a reflector. One example of a suitable p-contact 24 includes a Ni/Ag/Ti multi-layer contact.

An n-contact 28 is deposited and patterned, such that n-contact 28 is disposed on the substantially flat surface of the n-type region 16 between the pixels 12. The n-contact 28 may include a single or multiple metal layers. The n-contact 28 may include, for example, an ohmic n-contact 130 in direct contact with the n-type region 16, and an n-trace metal layer 132 formed over the ohmic n-contact 130. The ohmic n-contact 130 may be, for example, a V/Al/Ti multi-layer contact. The n-trace metal 132 may be, for example, a Ti/Au/Ti multi-layer contact.

The n-contact 28 and the p-contact 24 are electrically isolated by a dielectric layer 134. Dielectric layer 134 may be any suitable material such as, for example, one or more oxides of silicon, and/or one or more nitrides of silicon, formed by any suitable method. Dielectric layer 134 covers n-contact 28. Openings formed in dielectric layer 134 expose p-contact 24.

A p-trace metal 136 is formed over the top surface of the device, and substantially covers the entire top surface. The p-trace metal 136 electrically connects to the p-contact 24 in the openings formed in dielectric layer 134. The p-trace metal 136 is electrically isolated from n-contact 28 by dielectric layer 134.

Multiple pixels 12 are included in a single UVLED. The pixels are electrically connected by large area p-trace metal 136 and the large area n-trace metal 132. The number of pixels may be selected based on the application and/or desired radiation output. A single UVLED, which includes multiple pixels, is illustrated in the following figures as UVLED 1.

In some embodiments, substrate 14 is sapphire. Substrate 14 may be, for example, on the order of a hundred of microns thick. Substrate 14 may remain part of the device in some embodiments, and may be removed from the semiconductor structure in some embodiments.

The UVLED may be square, rectangular, or any other suitable shape when viewed from the top surface of substrate 14, when the device is flipped relative to the orientation illustrated in FIG. 3. Each UVLED 1 may be, for example, 1 mm square in some embodiments, 0.3 mm square in some embodiments, between 0.3 mm and 1 mm on a side in some embodiments, or any other suitable dimension.

Returning to FIG. 1, mount 10 may be any suitable material. Mount 10 may be highly thermally conductive (for example, with a thermal conductivity of at least 170 W/mK in some embodiments), highly electrically insulating, and mechanically rigid (for example, with a coefficient of thermal expansion that matches or is close to that of UVLED 1). Examples of suitable materials for mount 10 include but are not limited to ceramic, diamond, AlN, beryllium oxide, silicon or electrically conductive material such as silicon, metal, alloy, Al, or Cu, provided the electrically conductive material is appropriately coated with an insulating layer such as silicon oxide, silicon nitride or aluminum oxide, or any other suitable material. In some embodiments, circuitry and/or other structures such as transient voltage suppression circuitry, driver circuitry, or any other suitable circuitry may be disposed within mount 10, or mounted on a surface of mount 10, such that the circuitry or other structures are electrically connected to UVLED 1, if necessary.

Conductive pads (not shown) may be formed on the top surface of the mount. UVLED 1 is electrically and physically connected to mount 10 through the pads. At least two electrically isolated pads may be provided per UVLED 1, one coupled to the n-type region of the UVLED and one coupled to the p-type region of the UVLED. The pads may be, for example, any material that is suitable for bonding UVLED 1 including, for example, gold, silver, tin-silver-copper (SAC), or gold-tin (AuSn). The pads may be formed on the surface of mount 10 by any suitable technique including, for example, plating.

The UVLED 1 may be attached to the mount 10 by, for example, solder, gold-gold interconnects, sintering silver, which includes silver nanoparticles and may be sintered at relatively low temperature (for example, 200° C.), or any other suitable connection.

Though a dome lens is illustrated in FIG. 1, lens 14 may be any suitable optic, such as a Fresnel lens, other lens, microlens array, a two dimensional structure such as a photonic crystal formed on a transparent plate, a transparent plate or layer, or other optic. Lens 14 may have a height of a few hundred microns to a few centimeters, depending on the structure. At the base, the surface that attaches to transparent material 12, the lens may be at least 0.5 mm in diameter in some embodiments, no more than 5 cm in diameter in some embodiments. The bottom surface of lens 14 is often wider than UVLED 1 as illustrated in FIG. 1, though this is not required. The lens is fabricated separately from the UVLED and attached over the UVLED, as described below.

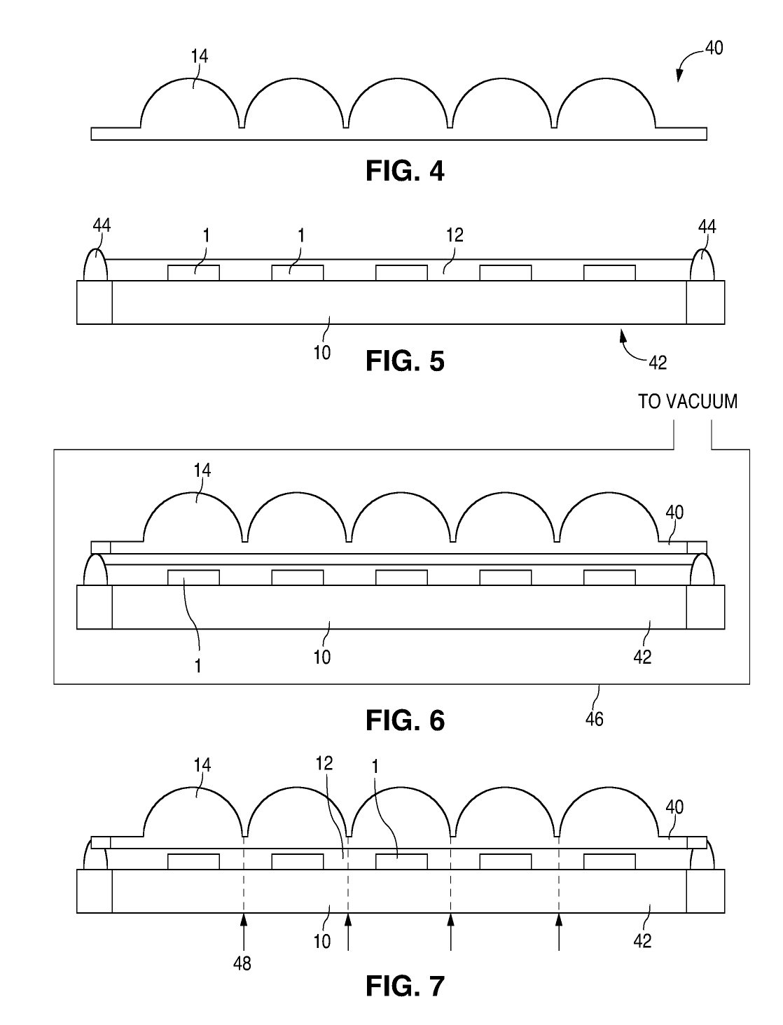

The structure illustrated in FIG. 1 may be formed, for example, as illustrated below in FIGS. 4, 5, 6 and 7. In FIG. 4, a panel 40 of individual lenses 14 is formed. Lenses 14 may be quartz, glass, sapphire, or any other suitable transparent and UV-resistant material, such as calcium fluoride or magnesium fluoride. Panel 14 may be formed by any suitable technique, such as grinding, molding, casting, or sintering. Panel 14 can be further coated with anti-reflection thin films.

Separate from the panel of lenses illustrated in FIG. 4, in FIG. 5 multiple UVLEDs 1 are attached to a panel 42 of individual mounts 10. As described above, UVLEDs 1 may be attached to mounts 10 by any suitable technique, such as soldering. Any structures necessary to electrically and/or physically connect UVLEDs 1 to mounts 10, such as wire bonds or metal bridges, may be formed in FIG. 5. Other structures such as electrostatic discharge protection chips may also be attached to UVLEDs 1 and/or to mounts 10 in FIG. 5.

In FIG. 5, a transparent adhesive material 12 is disposed over UVLEDs 1. In some embodiments, transparent adhesive material 12 is liquid at room temperature, and may be cured to a solid at elevated temperature. Any suitable material that is UV-transparent and UV-resistant may be used. In some embodiments, material 12 is a liquid mixture of polyvinylsiloxane, polyalkylalkenylsiloxane, and dimethylhydrogenpolysiloxane. Transparent material 12 may be formed over UVLEDs 1 by any suitable technique, such as dispensing. As illustrated in FIG. 5, in some embodiments, a structure that acts as a dam 44 is formed or positioned at the edges of the panel 42 of mounts 10. A liquid transparent material 12 may be dispensed or otherwise added to the area within the dam, in a quantity sufficient for example to cover UVLEDs 1. The liquid mixture 12 can be defoamed in a vacuum desiccator.

In FIG. 6, a panel 40 of lenses 14 is aligned over a panel 42 of UVLEDs 1 disposed on individual mounts 10. The aligned structure can be pressed together in a vacuum environment and bonded together by curing the liquid material 12 into solid material at elevated temperature. By bonding under vacuum environment, there is little or no air or ambient gas trapped between panel 40 and panel 42. Any suitable apparatus may be used to bond panel 40 and panel 42 together. In some embodiments, a wafer bonder may be used, such as DXB 880 Series Wafer Bonder from Dynatex.

The resulting structure is illustrated in FIG. 7. Individual lenses 14 are aligned over individual UVLEDs 1. After bonding panel 40 to panel 42, the thickness of transparent material 12 between the top of UVLED 1 and the bottom of lens 14 may be at least 10 microns in some embodiments, no more than 1 mm in some embodiments, and at least 100 microns in some embodiments.

Individual devices are separated from the bonding structure by singulating in regions 48. Any suitable singulation technique may be used, such as sawing with a blade. Any suitable apparatus may be used to saw the bonded panels, such as ADT 7130 series dicing system. Because the mount 10 is singulated at the same time as lens 14, as illustrated in FIG. 1, the width of the bottom surface of the lens (where the lens contacts transparent material 12) may be the same as the width of mount 10.

Though FIG. 7 illustrates a single lens disposed over a single UVLED, and the resulting structure diced into individual UVLEDs, in some embodiments, a lens may be disposed over multiple UVLEDs. In some embodiments, groups of UVLEDs may be diced as a single piece from the bonded panels, such that the lens or lenses associated with the group, and/or the mounts associated with the group, remain attached to each other.

Having described the invention in detail, those skilled in the art will appreciate that, given the present disclosure, modifications may be made to the invention without departing from the spirit of the inventive concept described herein. In particular, different features and components of the different devices described herein may be used in any of the other devices, or features and components may be omitted from any of the devices. A characteristic of a structure described in the context of one embodiment, may be applicable to any embodiment. Therefore, it is not intended that the scope of the invention be limited to the specific embodiments illustrated and described.

What is being claimed is:

1. A device comprising:
a light emitting diode (UVLED) comprising a semiconductor structure comprising an active layer disposed between an n-type region and a p-type region, wherein the active layer emits UV radiation;
a ceramic mount, wherein the UVLED is attached to the mount;
a lens disposed over the UVLED, wherein the lens is one of quartz, sapphire, and glass;
wherein a surface of the lens closest to the UVLED is the same width as the ceramic mount.

2. The device of claim 1 further comprising a transparent material disposed between the UVLED and the lens.

3. The device of claim 2 wherein the transparent material comprises polyvinylsiloxane and polyalkylalkenylsiloxane.

4. The device of claim 2 wherein the transparent material adheres the lens to the UVLED.

5. A method comprising:
attaching a plurality of light emitting diodes (UVLEDs) to a panel of mounts, each UVLED comprising a semiconductor structure comprising an active layer disposed between an n-type region and a p-type region, wherein the active layer emits UV radiation;
attaching a panel of lenses to the plurality of UVLEDs; and
after said attaching a panel of lenses, dicing the panel of mounts and the panel of lenses.

6. The method of claim 5 wherein after said dicing, a surface of each lens closest to the UVLED has a same width as the mount over which the lens is disposed.

7. The method of claim 5 wherein each mount is ceramic and each lens is one of quartz, glass, and sapphire.

8. The method of claim 5 wherein attaching a panel of lenses to the plurality of UVLEDs comprises dispensing a liquid transparent material over the UVLEDs, aligning the panel of lenses with the UVLEDs, and curing the transparent material into a solid adhesive.
